(19) United States
(12) Patent Application Publication
(10) Pub. No.: US 2003/0045094 A1
(43) Pub. Date: Mar. 6, 2003

(54) Method and apparatus for manufacturing semiconductor devices

(75) Inventors: Hideharu Itatani, Tokyo (JP); Atsushi Sano, Tokyo (JP)

Correspondence Address: MCGINN & GIBB, PLLC, 8321 OLD COURTHOUSE ROAD, SUITE 200, VIENNA, VA, 22182-3817, US

(73) Assignee: HITACHI KOKUSAI ELECTRIC INC., Tokyo (JP)

(21) Appl. No.: 10/228,253

(22) Filed: Aug. 27, 2002

(30) Foreign Application Priority Data
Aug. 28, 2001 (JP) 2001-258556

(51) Int. Cl. H01L 21/44; H01L 21/469; H01L 21/31

(52) U.S. Cl. 438/686; 438/761; 438/785

(57) ABSTRACT

A semiconductor manufacturing method and a semiconductor manufacturing apparatus are capable of manufacturing semiconductor devices with excellent step coverage and high throughput and at low cost. A substrate (1) is arranged in a thermal CVD apparatus which includes a reaction chamber (5), a gas supply port (7) through which ruthenium precursor gases for depositing ruthenium films or ruthenium oxide films on a substrate (1) are supplied to the reaction chamber (5), and a gas exhaust port 8 through which the precursor gases are exhausted from the reaction chamber (5). A first ruthenium precursor gas is caused to flow from the gas supply port (7) toward the substrate (1) so that a first ruthenium film or a first ruthenium oxide film is deposited on the substrate (1). With the first ruthenium film or the first ruthenium oxide film being employed as an underlayer, a second ruthenium film or a second ruthenium oxide film having a thickness greater than that of the underlayer is deposited by using a second ruthenium precursor gas different from the first ruthenium precursor gas.

### BACKGROUND OF THE INVENTION

The present invention relates to a method and an apparatus for manufacturing semiconductor devices in which ruthenium films or ruthenium oxide films are formed on a substrate.

2. Description of the Related Art

The formation or deposition of thin ruthenium films, major candidates of next generation's DRAM electrodes, using a sputtering process, has been technically established and frequently employed at the research level. However, the formation or deposition of thin films by the use of sputtering is defective in the ability of covering stepped portions (hereinafter referred to as step coverage), and hence a thermal CVD method having a excellent step covering ability is preferred for mass production processes and has been actively developed.

In the thermal CVD method, deposition precursors (raw materials) are generally in the form of a liquid of an organic metal, a solution with a powder of an organic metal dissolved in a solvent or the like, these materials being vaporized by means of an vaporizer or bubbling and supplied to a substrate. Here, note that bisethyl-cyclopentadienyl-ruthenium (Ru(C₂H₅C₅H₄)₂) is referred to as such a raw material.

In general, a ruthenium film or a ruthenium oxide film is formed on an upper portion of an interlayer insulation film such as a silicon oxide film, a silicon nitride film, etc., or on an upper portion of a barrier metal layer formed of a metal such as TiN, TaN, WN, etc. However, with such an underlying layer or underlayer, there is a deficiency in that a delay in deposition would be caused in cases where the ruthenium film or the ruthenium oxide film is formed by means of a thermal CVD method while particularly using bisethyl-cyclopentadienyl-ruthenium and oxygen as raw materials. On the other hand, the step coverage in the case of using above-mentioned precursor is good in a deposition temperature condition of about 300° C. (i.e., 290° C. to 330° C.), but at this temperature condition, a delay in deposition will be caused, taking time until thin films of a desired thickness have been formed. Thus, this is not suitable for mass production. Moreover, when the deposition of films is performed at a temperature higher than 330° C., the time for the formation of films can be shortened, but on the contrary, there arises a deficiency in that the step coverage is impaired.

On the other hand, in the case where ruthenium films or ruthenium oxide films are deposited on a substrate by means of a thermal CVD method, a deposition delay will not be caused even at a temperature as high as about 300° C. if a ruthenium film or a ruthenium oxide film is formed in advance on the substrate by the use of a sputtering apparatus. However, this results in a further disadvantage that it is necessary to use two reactors, thus reducing the throughput and increasing the cost of equipment.

In view of these circumstances, the inventors already proposed a two-step deposition process in Japanese Patent Application No.2001-24360 in which in case where deposition is performed using bisethyl-cyclopentadienyl-ruthenium alone, the deposition conditions in an initial deposition step are made different from those in a main deposition step which suppresses a deposition delay. However, it has been found from subsequent experiments that a process window for meeting the quality of films required at the production level is narrow, and hence further approaches in the two-stage deposition process are needed.

### SUMMARY OF THE INVENTION

Accordingly, the object of the present invention is to provide a method for manufacturing semiconductor devices at low cost, which is excellent in the step coverage and the throughput.

Bearing the above object in mind, according to one aspect of the present invention, there is provided a method for manufacturing semiconductor devices, including a process for depositing ruthenium films or ruthenium oxide films on a substrate by using a gas vaporized from a ruthenium liquid precursor and an oxygen-containing gas. The method includes: an initial deposition step for depositing a first ruthenium film or a first ruthenium oxide film on the substrate; and a main deposition step for depositing a second ruthenium film or a second ruthenium oxide film on the first ruthenium film or the first ruthenium oxide film formed in the initial deposition step by using a ruthenium liquid precursor different from the one used in the initial deposition step, the second ruthenium film or the second ruthenium oxide film having a thickness greater than that of the first ruthenium film or the first ruthenium oxide film. With this semiconductor manufacturing method, it is possible to provide semiconductor devices which are excellent in step coverage, high in throughput, and low in the cost of manufacture.

In a preferred form of the present invention, the initial deposition step and the main deposition step are continuously performed in one and the same reaction chamber by a thermal CVD method. Thus, semiconductor devices can be manufactured at lower costs.

In another preferred form of the present invention, the ruthenium liquid precursor used in the initial deposition step has a deposition delay time shorter than that of the ruthenium liquid precursor used in the main deposition step. Accordingly, semiconductor devices can be manufactured with excellent step coverage and high throughput and at low cost.

In a further preferred form of the present invention, the initial deposition step and the main deposition step are performed at the same temperature. Thus, semiconductor devices can be manufactured with excellent step coverage and high throughput and at low cost.

In a still further preferred form of the present invention, the initial deposition step and the main deposition step are performed at a temperature in the range of 285-310° C. Thus, it is possible to provide semiconductor devices which are excellent in step coverage, high in throughput, and low in the cost of manufacture.

In a yet further preferred form of the present invention, the ruthenium liquid precursor used in the initial deposition step is Ru[CH₃COCHCO(CH₂)₃CH₃]₃. Thus, semiconductor devices can be manufactured with excellent step coverage and high throughput and at low cost.

In a further preferred form of the present invention, processing is performed at a temperature in the range of 250-310° C. by using Ru[CH₃COCHCO(CH₂)₃CH₃]₃ as a ruthenium precursor in the initial deposition step, and deposition is performed at a temperature in the range of 285-320° C. by using Ru(C₂H₅C₅H₄)₂ as a ruthenium liquid precursor in the main deposition step. Thus, semiconductor devices can be provided which are further excellent in step coverage, high in throughput, and low in the cost of manufacture.

According to another aspect of the present invention, there is provided a method for processing a substrate, including a process in which ruthenium films or ruthenium oxide films are deposited on a substrate by using a gas vaporized from a ruthenium liquid precursor and an oxygen-containing gas. The method includes: an initial deposition step for depositing a first ruthenium film or a first ruthenium oxide film on the substrate; and a main deposition step for depositing a second ruthenium film or a second ruthenium oxide film on the first ruthenium film or the first ruthenium oxide film formed in the initial deposition step, by using a ruthenium liquid precursor different from the one used in the initial deposition step. The second ruthenium film or the second ruthenium oxide film has a thickness greater than that of the first ruthenium film or the first ruthenium oxide film. Accordingly, it is possible to provide a substrate processing method which is excellent in the step coverage, high in throughput, and low in the cost of manufacture.

According to a further aspect of the present invention, there is provided a apparatus for manufacturing semiconductor devices, which includes: a reaction chamber adapted to accommodate a substrate; a heater for heating the substrate; a first ruthenium precursor gas supply system for supplying to the reaction chamber a first ruthenium precursor gas, which is used to deposit a ruthenium film or a ruthenium oxide film on the substrate; a second ruthenium precursor gas supply system for supplying to the reaction chamber a second ruthenium precursor gas which is different from the first ruthenium precursor gas; a first control part for operating the first ruthenium precursor gas supply system to supply a first ruthenium precursor gas to the reaction chamber so that a first ruthenium film or a first ruthenium oxide film is deposited on the substrate by a thermal CVD method; a second control part for operating the second ruthenium precursor gas supply system to supply a second ruthenium precursor gas to the reaction chamber after the deposition of the first ruthenium film or the first ruthenium oxide film according to the first control part, so that a second ruthenium film or a second ruthenium oxide film is deposited according to a thermal CVD method on the first ruthenium film or the first ruthenium oxide film formed by the first control part. The second ruthenium film or the second ruthenium oxide film has a thickness greater than that of the first ruthenium film or the first ruthenium oxide film. With this configuration, it is possible to provide a semiconductor manufacturing apparatus capable of manufacturing semiconductor devices which are excellent in step coverage, high in throughput, and low in the cost of manufacture.

Preferably, the semiconductor manufacturing apparatus further includes a timer for measuring a first supply time for which the first ruthenium precursor gas is supplied to the reaction chamber, and a second supply time for which the second ruthenium precursor gas is supplied to the reaction chamber. The first control part and the second control part perform their control operations based on the first and second supply times measured by the timer, respectively.

The above and other objects, features and advantages of the present invention will become more readily apparent to those skilled in the art from the following detailed description of preferred embodiments of the present invention taken in conjunction with the accompanying drawings.

### DESCRIPTION OF THE DRAWINGS

FIG. 1 is a view explaining the relation between the deposition time and the ruthenium film thickness in case where a ruthenium film is deposited on a substrate by using a precursor gas of Ru(EtCp)₂ or Ru(OD)₃.

FIG. 2 is a view explaining the relation between the deposition time and the ruthenium film thickness in case where after an initial deposition step has been performed in which a first ruthenium film is deposited on a substrate by using a Ru(OD)₃ precursor gas, a main deposition step is carried out to deposit a second ruthenium film on the first ruthenium film which is utilized as an underlayer, by using a Ru(EtCp)₂ precursor gas.

FIG. 3 is a view explaining the relation between the step coverage and the deposition rate with respect to the deposition temperature when a ruthenium film is deposited on a substrate by using a Ru(OD)₃ precursor gas.

FIG. 4 is a view explaining the relation between the step coverage and the deposition rate with respect to the deposition temperature in case where after an initial deposition step has been performed in which a first ruthenium film is deposited on a substrate by using a Ru(OD)₃ precursor gas, a main deposition step is carried out to deposit a second ruthenium film on the first ruthenium film which is utilized as an underlayer, by using a Ru(EtCp)₂ precursor gas.

FIG. 5 is a view explaining one example of a thermal CVD apparatus which can be used by the present invention.

FIG. 6 is a cross sectional view showing a part of a DRAM including ruthenium films or ruthenium oxide films formed by using the manufacturing method of the present invention

### DESCRIPTION OF THE PREFERRED EMBODIMENTS

A method of manufacturing semiconductor devices according to the present invention includes an initial deposition step in which a first ruthenium film or a first ruthenium oxide film is deposited on a substrate by using an oxygen-containing gas and a gas which is vaporized from a ruthenium liquid raw material, and a main deposition step in which a second ruthenium film or a second ruthenium oxide film is deposited on the first ruthenium film or the first ruthenium oxide film which behaves as an underlying layer which is hereinafter referred to as an underlayer.

In the initial deposition step, the ruthenium film or the ruthenium oxide film is formed by using the ruthenium liquid precursor with a short deposition delay time, and in the following main deposition step, the deposition of the second ruthenium film or the second ruthenium oxide film is carried out on the first ruthenium film or the first ruthenium oxide film which has been formed in the initial deposition step. As a result, there is caused substantially no deposition delay. Accordingly, the ruthenium films or the ruthenium oxide films can be formed with conditions for good step coverage without generating a deposition delay.

For instance, in cases where a solute for the ruthenium liquid precursor is Ru[CH₃COCHCO(CH₂)₃CH₃]₃ (tris-2,4-octanedionato-ruthenium, which is hereinafter abbreviated as Ru(OD)₃) and a solvent therefor is butyl acetate or the like, the following examples are shown as suitable deposition conditions in the initial deposition step. That is, the temperature is 250° C.-310° C., and more preferably from 260° C. to 310° C.; the pressure is 13.3 Pa-666.5 Pa (0.1 Torr-5 Torr); the flow rate of the ruthenium liquid precursor is 0.1 ccm-2 ccm; and the flow rate of the oxygen gas is 10 sccm-500 sccm; and the deposition time is 1 minute or less.

For instance, when the ruthenium liquid precursor is Ru(C₂H₅C₅H₄)₂ (bisethyl-cyclopentadienyl-ruthenium, which is hereinafter abbreviated as Ru(EtCp)₂) alone, the following examples are shown as suitable deposition conditions in the main deposition step. That is, the temperature is 285° C.-320° C., and more preferably from 290° C. to 320° C.; the pressure is 67 Pa-1,333 Pa (0.5 Torr-10 Torr); the flow rate of a ruthenium liquid precursor is 0.01 ccm-0.1 ccm; and the flow rate of the oxygen gas is 5 sccm-200 sccm; and the deposition time is 60 seconds-300 seconds. In addition, if the above-mentioned deposition conditions in the main deposition step are properly determined according to the purposes for processing, it is also possible to provide the deposition of any of ruthenium films and ruthenium oxide films.

Moreover, it is preferable to perform the initial deposition step and the main deposition step continuously in one and the same reaction chamber in terms of costs, i.e., throughput, the cost of equipment, etc. Furthermore, it is desirable that both the initial deposition step and the main deposition step be performed at temperatures of 285° C.-310° C., more preferably from 290° C. to 310° C., which are in a suitable temperature range in either of these deposition steps, thereby making it possible to further improve the effects of the present invention.

Preferably, the thickness of the ruthenium film or the ruthenium oxide film formed in the initial deposition step is 5 nm-15 nm for instance, and the thickness of the ruthenium film or the ruthenium oxide film formed in the main deposition step is 10 nm-50 nm for instance. Here, it is necessary that the thickness of the ruthenium film or the ruthenium oxide film formed in the main deposition step is greater than the film thickness thereof formed in the initial deposition step.

In addition, the conditions other than the above can be properly set as in conventional well-known thermal CVD methods.

The underlayer provided as necessary under the ruthenium film or the ruthenium oxide film in the present invention is not specifically limited but may be, for instance, SiO₂, Si₃N₄, TiN, TaN, WN, Ta₂O₅, TiAlN, BST etc.

Also, the oxygen-containing gas used in the present invention can be properly selected from various kinds of gases according to the usage, but one typical example thereof is oxygen (O₂).

Operation

The process of manufacture of the present invention includes an initial deposition step for depositing a first ruthenium film or a first ruthenium oxide film on a substrate, and a main deposition step for depositing on the first ruthenium film or the first ruthenium oxide film a second ruthenium film or a second ruthenium oxide film having a thickness greater than that of the first ruthenium film or the first ruthenium oxide film by using a ruthenium liquid precursor different from the one employed in the initial deposition step.

As described above, according to the present invention, for example, a Ru(OD)₃ precursor gas can be used in the initial deposition step, and a Ru(EtCp)₂ precursor gas can be used in the main deposition step, but there arises a drawback that in cases where ruthenium films or ruthenium oxide films are deposited on a substrate by using the Ru(OD)₃ precursor gas alone, the electrical resistance of the deposited films becomes high, providing a poor electric characteristic, as compared with the case where the Ru(EtCp)₂ precursor gas is used for deposition in combination with the Ru(OD)₃ precursor gas. It is thought that this is due to the following reason. That is, when deposition is performed by using the Ru(OD)₃ precursor gas alone, impurities such as C, H, O, etc., can be easily taken into the deposited films, so the electric characteristic thereof is deteriorated by these impurities. On the other hand, when deposition is carried out by using the Ru(EtCp)₂ precursor gas alone, there arises another drawback that the uniformity in the thickness of the deposited films over the surface of a wafer is poor though the deposition delay time can be shortened. It is thought that this is due to the following reason. That is, when the Ru(EtCp)₂ precursor gas is used, the deposition delay time can be shortened by employing a prescribed condition in the initial deposition step, but it is impossible to completely prevent the generation of the deposition delay time. Accordingly, the film thickness over the wafer surface in the initial stage of the deposition is caused to vary due to a deposition delay generated in the initial deposition step.

In contrast to the above, according to the present invention, the above-mentioned drawbacks was able to be obviated by using a Ru(OD)₃ precursor gas in the initial deposition step of the two-step deposition process and by using a Ru(EtCp)₂ precursor gas in the following main deposition step thereof. The reason is as follows. In the initial deposition step, variations in the film thickness over the surface of the wafer can be suppressed by using the Ru(OD)₃ precursor gas with no deposition delay, thus improving the uniformity in the film thickness as compared with the case of using the Ru(EtCp)₂ precursor gas. In the main deposition step, the electrical resistance of the deposited films can be lowered by using the Ru(EtCp)₂ precursor gas in which it is comparatively difficult for impurities to be taken into the deposited films during deposition thereof (that is, the electrical resistance becomes comparatively low) in comparison with the case of using the Ru(OD)₃ precursor gas. Therefore, the amount of impurities coming into the films can be decreased, thus resulting in reduction in the deterioration of the electric characteristic.

In this manner, according to the present invention, it is possible to provide a method and an apparatus for manufacturing semiconductor devices with excellent step coverage and high throughput and at low cost.

### EXAMPLE

Hereinafter, the present invention will be explained in more detail according to an example thereof.

FIG. 1 is a view explaining the relation between the deposition time and the ruthenium film thickness when a ruthenium film is deposited on a substrate by using a Ru(EtCp)₂ precursor gas or a Ru(OD)₃ precursor gas. An underlayer was composed of SiO₂.

In FIG. 1, the time indicated by a cross point at which a straight line connecting plots at each deposition temperature intersects the horizontal axis (i.e., deposition time axis) becomes a deposition delay time. In this figure, black plots represent the cases where a Ru(OD)₃ precursor gas was used, and a straight line connecting black plots at each of the temperatures of 280, 300 and 320° C. almost intersects the origin. In other words, this indicates that there is no deposition delay time in these cases.

On the other hand, white or hollow plots in FIG. 1 represent the cases where a Ru(EtCp)₂ precursor gas is used, and straight lines connecting white or hollow plots at the temperatures of 310° C. and 330° C. intersect the horizontal axis at the times of 12 minutes and 4 minutes, respectively, and hence it is understood that there exist deposition delay times in these cases. In other words, it is understood that the deposition times in these cases are extended by the deposition delay times, respectively, which becomes a cause of reducing the throughput.

Here, note that other deposition conditions in FIG. 1 are that the pressure is 133 Pa (1 Torr); the flow rate of the ruthenium liquid precursor is 1 ccm; and the flow rate of the oxygen gas is 160 sccm.

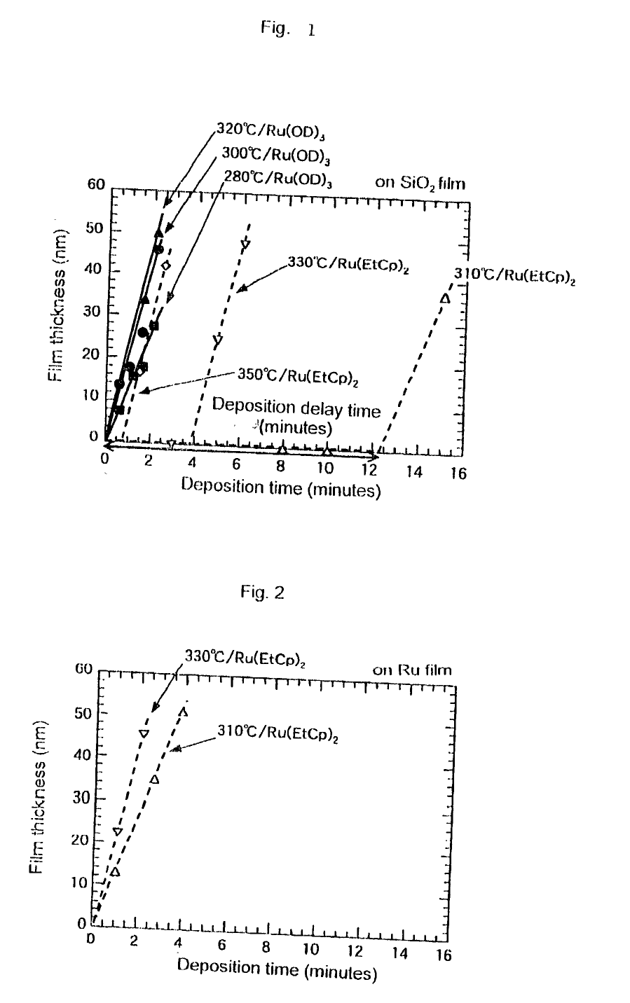

FIG. 2 is a view explaining the relation between the deposition time and the ruthenium film thickness in cases where after an initial deposition step has been performed in which a ruthenium film is deposited on a substrate by using a Ru(OD)₃ precursor gas, a main deposition step is carried out by using a Ru(EtCp)₂ precursor gas with the thus deposited ruthenium film being made as an underlayer. Note that the film thickness in FIG. 2 means the thickness of the deposited film formed in the main deposition step, i.e., the film thickness obtained by subtracting the thickness of the deposited film formed in the initial deposition step from the total thickness of the deposited films formed in the initial and main deposition steps. From FIG. 2, it can be seen that there is no deposition delay time in the main deposition step after the initial deposition step in either case where the deposition temperature is 310° C. or 330° C.

Accordingly, it is possible to obtain a wide process window in the main deposition step without being influenced by deposition delays.

Here, note that other deposition conditions in FIG. 2 are as follows. That is, in the initial deposition step, the pressure is 133 Pa (1 Torr); the flow rate of the ruthenium liquid precursor is 1 ccm; and the flow rate of the oxygen gas is 35 sccm. In the main deposition step, the pressure is 133 Pa (1 Torr); the flow rate of the ruthenium liquid precursor is 1 ccm; and the flow rate of the oxygen gas is 160 sccm.

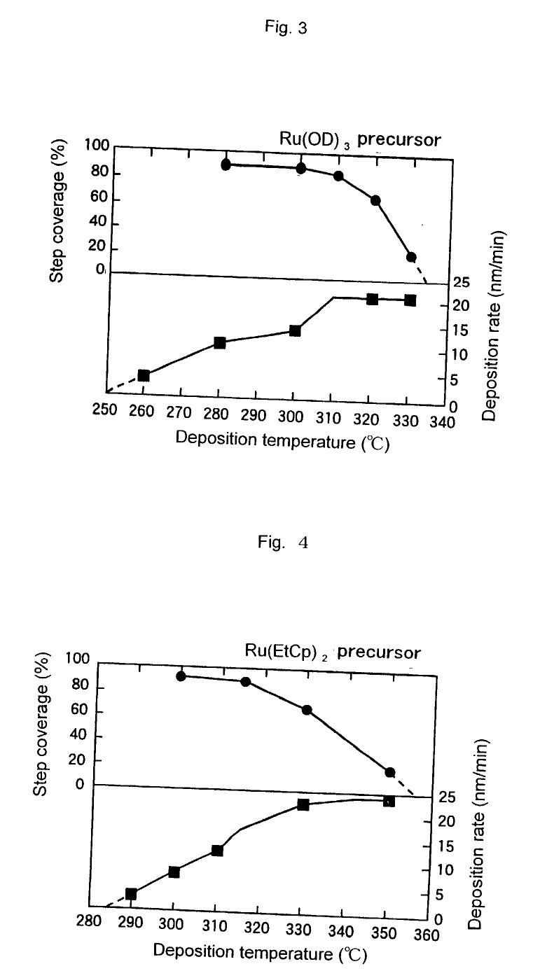

FIG. 3 is a view explaining the relation between the step coverage and the deposition rate with respect to deposition temperature in case where a ruthenium film is deposited on a substrate by using a Ru(OD)₃ precursor gas. In this case, an underlayer was a SiO₂ film. In this figure, black or filled round plots represent step coverages, and black or filled square plots represent deposition rates.

In FIG. 3, a deposition temperature range in which semiconductor devices can be manufactured is that the deposition rate is greater than 0 nm/minute and the step coverage is greater than 0%. That is, the deposition temperature range is 250° C.-335° C., and more preferably from 260° C. to 330° C.

Here, it is to be noted that other deposition conditions in FIG. 3 are as follows. That is, the pressure is 133 Pa (1 Torr); the flow rate of the ruthenium liquid precursor is 1 ccm; and the flow rate of the oxygen gas is 35 sccm.

FIG. 4 is a view explaining the relation between the step coverage and the deposition rate with respect to the deposition temperature in case where after an initial deposition step has been performed in which a first ruthenium film is deposited on a substrate by using a Ru(OD)₃ precursor gas, a main deposition step is carried out to deposit a second ruthenium film on the first ruthenium film which is utilized as an underlayer, by using a Ru(EtCp)₂ precursor gas. In this figure, black or filled round plots represent step coverages, and black or filled square plots represent deposition rates.

Similar to FIG. 3, a deposition temperature range in which semiconductor devices can be manufactured with a deposition rate greater than 0 nm/minute and a step coverage greater than 0% is 285° C.-355° C., and more preferably from 290° C. to 350° C.

Note that other deposition conditions in FIG. 4 are as follows. That is, in the initial deposition step, the pressure is 133 Pa (1 Torr); the flow rate of the ruthenium liquid precursor is 1 ccm; and the flow rate of the oxygen gas is 35 sccm. In the main deposition step, the pressure is 133 Pa (1 Torr); the flow rate of the ruthenium liquid precursor is 1 ccm; and the flow rate of the oxygen gas is 160 sccm.

Accordingly, from the deposition temperature ranges of FIGS. 3 and 4 in which semiconductor devices can be manufactured, it can be understood that if the initial deposition step and the main deposition step are carried out continuously at the same temperature in the range of 285° C.-335° C., and more preferably from 290° C. to 330° C., in the one and same reaction chamber, it will be possible to provide semiconductor devices with high throughput and at low cost.

Note that the temperatures capable of providing excellent step coverage (i.e., step coverage of 80% or more) are 310° C. or less in the case of using the Ru(OD)₃ precursor gas, as can be seen from FIG. 3, and 320° C. or less in the case of using the Ru(EtCp)₂ precursor gas, as can be seen from FIG. 4. Accordingly, in case where the Ru(OD)₃ precursor gas is used, by controlling the deposition temperature to be in a range from 250° C. to 310° C., and more preferably from 260° C. to 310° C., it is possible to perform deposition of films while keeping a step coverage of 80% or more. On the other hand, in case where the Ru(EtCp)₂ precursor gas is used, by controlling the deposition temperature to be in a range from 285° C. to 320° C., and more preferably from 290° C. to 320° C., it is possible to perform deposition of films while keeping a step coverage of 80% or more. From these facts, it is seen that by continuously performing the initial deposition step and the main deposition step at the same temperature within a range of 285° C.-310° C., and more preferably from 290° C. to 310° C., in the same reaction chamber, it is possible to provide semiconductor devices of excellent step coverage with high throughput and at low cost.

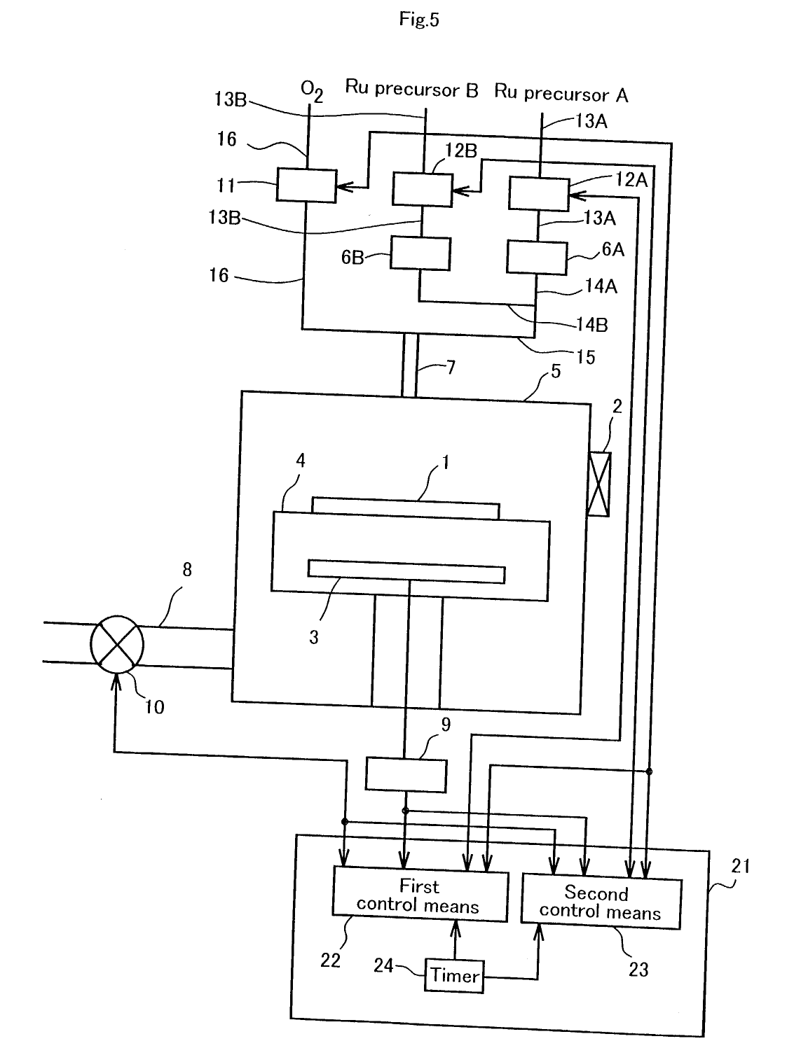

FIG. 5 is a view explaining one example of a thermal CVD apparatus which can be used by the present invention. The CVD apparatus shown in FIG. 5 is provided with a substrate holder 4 having a heater 3 arranged in a reaction chamber 5, and a gas supply port 7 and a gas exhaust port 8 are connected with the reaction chamber 5. A Ru precursor gas supply pipe 15 and an oxygen gas supply pipe 16 are connected with the gas supply port 7. A first Ru precursor gas supply pipe 14A and a second Ru precursor gas supply pipe 14B are connected with the Ru precursor gas supply pipe 15 on an upstream side of the gas supply port 7 at a location a prescribed distance apart therefrom. A first Ru liquid precursor supply pipe 13A is connected with the first Ru precursor gas supply pipe 14A through a vaporizer 6A on an upstream side thereof, with a fluid flow rate control device 12A being arranged on the first Ru liquid precursor supply pipe 13A. A second Ru liquid precursor supply pipe 13B is connected with the second Ru precursor gas supply pipe 14B through a vaporizer 6B on an upstream side thereof, with a fluid flow rate control device 12B being arranged on the second Ru liquid precursor supply pipe 13B. An oxygen gas flow rate control device 11 is arranged on the oxygen gas supply pipe 16 on an upstream side of the gas supply port 7 at a location a prescribed distance apart therefrom. A pressure control device 10 for controlling the pressure in the reaction chamber 5 is arranged on the gas exhaust port 8. A temperature control device 9 for controlling the temperature of the heater 3 is connected with the heater 3. A gate valve 2 through which a substrate is transported into and out of the reaction chamber 5 is mounted on the reaction chamber 5 at an appropriate location thereof.

The temperature control device 9, the oxygen gas flow rate control device 11, the fluid flow rate control device 12A and the pressure control device 10 are connected with a first control means 22 incorporated in a main control device 21 of the semiconductor manufacturing apparatus, so that the initial deposition step is performed under the deposition control of the first control means 22 to form a first ruthenium film or a first ruthenium oxide film as an underlayer on the substrate 1. Also, the temperature control device 9, the oxygen gas flow rate control device 11, the fluid flow rate control device 12B and the pressure control device 10 are connected with a second control means 23 incorporated in the main control device 21 of the semiconductor manufacturing apparatus, so that the main deposition step is performed under the deposition control of the second control means 23 to form a second ruthenium film or a second ruthenium oxide film on the first ruthenium film or the first ruthenium oxide film, the thickness of the second ruthenium film or the second ruthenium oxide film thus formed being greater than that of the first ruthenium film or the first ruthenium oxide film. The time management of the initial deposition step and the main deposition step is carried out by means of a timer 24 incorporated in the main control device 21. Here, note that in the above configuration, the first Ru liquid precursor supply pipe 13A, the fluid flow rate control device 12A, the vaporizer 6A, the first Ru precursor gas supply pipe 14A and the Ru precursor gas supply pipe 15 together constitute a first ruthenium precursor gas supply system of the present invention. In addition, the second Ru liquid precursor supply pipe 13B, the fluid flow rate control device 12B, the vaporizer 6B, the second Ru precursor gas supply pipe 14B and the Ru precursor gas supply pipe 15 together constitute a second ruthenium precursor gas supply system of the present invention. Moreover, the fluid flow rate control device 12A, the oxygen gas flow rate control device 11, the pressure control device 10, the temperature control device 9, the timer 24 and the first control means 22 together constitute a first control part of the present invention. Furthermore, the fluid flow rate control device 12B, the oxygen gas flow rate control device 11, the pressure control device 10, the temperature control device 9, the timer 24 and the second control means 23 together constitute a second control part of the present invention.

In the above-mentioned configuration, a substrate 1 is transported into the reaction chamber 5 through the gate valve 2 to be disposed on the substrate holder 4 provided with the heater 3 by means of a delivery robot (not shown). The heater 3 is then caused to move in an upward direction to a prescribed position by means of a lift mechanism (not shown) so that it is able to heat the substrate 1 to a desired temperature. The deposition process of the present invention can be performed in the following manner for instance.

After the substrate 1 is heated for a prescribed period of time, the pressure in the reaction chamber 5 is stabilized to a desired pressure level. Then, an initial deposition step and a main deposition step are performed by introducing oxygen and ruthenium precursor gases vaporized by the vaporizer 6, which are used to form ruthenium films or ruthenium oxide films on the substrate 1, from the gas supply port 7 and exhausting them from the gas exhaust port 8. Note that a first ruthenium (Ru) precursor A is used for the initial deposition step for instance, and a second ruthenium (Ru) precursor B is used for the main deposition step for instance. Ru(OD)₃ is preferable as the first ruthenium precursor A for the initial deposition step, and Ru(EtCp)₂ is preferable as the second ruthenium precursor B for the main deposition step. In addition, the temperature, the pressure, the flow rate of oxygen and the flow rate of a ruthenium liquid precursor in each process step are controlled by the temperature control device 9, the pressure control device 10, the oxygen gas flow rate control device 11, the fluid flow rate control device 12A or 12B, respectively. When the main deposition step has been completed, the substrate 1 is carried out from the reaction chamber 4 by means of the unillustrated delivery robot.

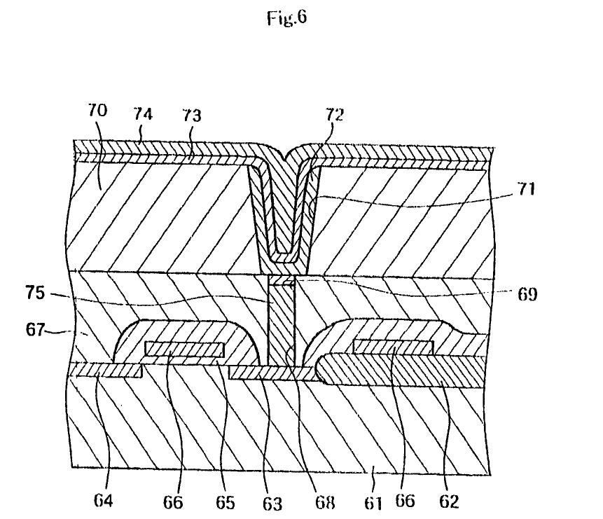

FIG. 6 is a cross sectional view which shows a part of a DRAM including ruthenium films or ruthenium oxide films formed by using the manufacturing method of the present invention.

As shown in FIG. 6, a field oxide film 62 for separating or isolating a transistor forming area is formed on the surface of a silicon substrate 61. A gate insulation film 65 is formed on an exposed portion of the surface of the silicon substrate 61 with a gate electrode 66 being formed on an upper portion of the gate insulation film 65 by means of patterning.

A source electrode 63 and a drain electrode 64 are formed in a self-adjusting manner through implantation of impurities according to an ion implantation method with the gate electrode 66 being used as a mask.

Subsequently, after deposition of an interlayer insulation film 67, a contact hole 68 is formed through the interlayer insulation film 67. A plug electrode 75 connected with the source electrode 63 and a barrier metal 69 are formed in the contact hole 68.

After deposition of another interlayer insulation film 70, another contact hole 71 is perforated through the interlayer insulation film 70. In the contact hole 71, a ruthenium film or a ruthenium oxide film is deposited according to the manufacturing method of the present invention, and thereafter a capacitive lower electrode 72 is formed through patterning.

A capacitive insulation film 73 made of Ta₂O₅ is formed on the capacitive lower electrode 72, and a capacitive upper electrode 74 composed of a ruthenium film or a ruthenium oxide film is formed on the capacitive insulation film 73 according to the manufacturing method of the present invention.

Although in the foregoing description, a specific ruthenium precursor gas has been referred to as a typical example for the purpose of explanation of the present invention, the present invention is not limited to the use of the specified ruthenium precursor gas. Also, the deposition conditions can be properly changed. In addition, the method of the present invention can be suitably adopted as a method for processing a substrate intended to efficiently deposit films on a substrate at low cost and with good step coverage.

As described above, according to the present invention, it is possible to provide a method and an apparatus for manufacturing semiconductor devices with excellent step coverage and high throughput and at low cost.

While the invention has been described in terms of preferred embodiments, those skilled in the art will recognize that the invention can be practiced with modifications within the spirit and scope of the appended claims.

What is claimed is:

1. A method for manufacturing semiconductor devices, including a process for depositing ruthenium films or ruthenium oxide films on a substrate by using a gas vaporized from a ruthenium liquid precursor and an oxygen-containing gas, said method comprising:
an initial deposition step for depositing a first ruthenium film or a first ruthenium oxide film on the substrate; and
a main deposition step for depositing a second ruthenium film or a second ruthenium oxide film on the first ruthenium film or the first ruthenium oxide film formed in the initial deposition step by using a ruthenium liquid precursor different from the one used in the initial deposition step, the second ruthenium film or the second ruthenium oxide film having a thickness greater than that of the first ruthenium film or the first ruthenium oxide film.

2. The method for manufacturing semiconductor devices according to claim 1, wherein said initial deposition step and said main deposition step are continuously performed in one and the same reaction chamber by a thermal CVD method.

3. The method for manufacturing semiconductor devices according to claim 1, wherein said ruthenium liquid precursor used in said initial deposition step has a deposition delay time shorter than that of said ruthenium liquid precursor used in said main deposition step.

4. The method for manufacturing semiconductor devices according to claim 1, wherein said initial deposition step and said main deposition step are performed at the same temperature.

5. The method for manufacturing semiconductor devices according to claim 4, wherein said initial deposition step and said main deposition step are performed at a temperature in the range of 285-310° C.

6. The method for manufacturing semiconductor devices according to claim 1, wherein said ruthenium liquid precursor used in said initial deposition step is Ru[CH₃COCHCO(CH₂)₃CH₃]₃.

7. The method for manufacturing semiconductor devices according to claim 1, wherein deposition is performed at a temperature in the range of 250-310° C. by using Ru[CH₃COCHCO(CH₂)₃CH₃]₃ as a ruthenium precursor in said initial deposition step, and deposition is performed at a temperature in the range of 285-320° C. by using Ru(C₂H₅C₅H₄)₂ as a ruthenium liquid precursor in said main deposition step.

8. A method for processing a substrate, including a process in which ruthenium films or ruthenium oxide films are deposited on a substrate by using a gas vaporized from a ruthenium liquid precursor and an oxygen-containing gas, said method comprising:
an initial deposition step for depositing a first ruthenium film or a first ruthenium oxide film on said substrate; and
a main deposition step for depositing a second ruthenium film or a second ruthenium oxide film on said first ruthenium film or said first ruthenium oxide film formed in said initial deposition step, by using a ruthenium liquid precursor different from the one used in said initial deposition step, said second ruthenium film or said second ruthenium oxide film having a thickness greater than that of said first ruthenium film or said first ruthenium oxide film.

9. A apparatus for manufacturing semiconductor devices, said apparatus comprising:
a reaction chamber adapted to accommodate a substrate;
a heater for heating said substrate;
a first ruthenium precursor gas supply system for supplying to said reaction chamber a first ruthenium precursor gas, which is used to deposit a ruthenium film or a ruthenium oxide film on said substrate;
a second ruthenium precursor gas supply system for supplying to said reaction chamber a second ruthenium precursor gas which is different from said first ruthenium precursor gas;
a first control part for operating said first ruthenium precursor gas supply system to supply a first ruthenium precursor gas to said reaction chamber so that a first ruthenium film or a first ruthenium oxide film is deposited on said substrate by a thermal CVD method;
a second control part for operating said second ruthenium precursor gas supply system to supply a second ruthenium precursor gas to said reaction chamber after the deposition of said first ruthenium film or said first ruthenium oxide film according to said first control part, so that a second ruthenium film or a second ruthenium oxide film is deposited according to a thermal CVD method on said first ruthenium film or said first ruthenium oxide film formed by said first control part, said second ruthenium film or said second ruthenium oxide film having a thickness greater than that of said first ruthenium film or said first ruthenium oxide film.

10. The semiconductor manufacturing apparatus according to claim 9, further comprising a timer for measuring a first supply time for which said first ruthenium precursor gas is supplied to said reaction chamber, and a second supply time for which said second ruthenium precursor gas is supplied to said reaction chamber, wherein said first control part and said second control part perform their control operations based on the first and second supply times measured by said timer, respectively.
